(19) United States
(12) Patent Application Publication
(10) Pub. No.: US 2026/0333973 A1
(43) Pub. Date: Oct. 22, 2026

(54) WIRING SUBSTRATE, MANUFACTURING METHOD THEREOF, AND ELECTRONIC APPARATUS

(71) Applicants: Hefei BOE Ruisheng Technology Co., Ltd., Hefei, Anhui (CN); BOE Technology Group Co., Ltd., Beijing (CN)

(72) Inventors: Tingwei HAN, Beijing (CN); Zouming XU, Beijing (CN); Jie WANG, Beijing (CN); Xintao WU, Beijing (CN); Jiawei XU, Beijing (CN); Ningyu LUO, Beijing (CN); Wenzhuo TANG, Beijing (CN)

(21) Appl. No.: 18/851,783

(22) PCT Filed: Nov. 30, 2023
(86) PCT No.: PCT/CN2023/135577

§ 371 Date: Sep. 27, 2024

(51) Int. Cl. H10H 29/49; H10H 29/01

(52) U.S. Cl. CPC H10H 29/49; H10H 29/012

(57) ABSTRACT

A wiring substrate includes: a base substrate, a plurality of signal lines, and a plurality of connection lines. The base substrate includes a first surface and a second surface arranged oppositely. The second surface includes a bonding region extending in a first direction, and fan-out regions located on both sides of the bonding region in a second direction. The fan-out regions are provided with a plurality of vias. The first direction intersects the second direction. The plurality of signal lines are disposed on the first surface, and orthographic projections of the plurality of signal lines on the base substrate extend in the second direction, passing through the bonding region and the fan-out regions. The plurality of connection lines are disposed on the second surface, and extend from the fan-out regions to the bonding region. The connection lines are coupled with the signal lines through the plurality of vias.

### CROSS REFERENCE TO RELATED APPLICATIONS

This application is a national phase entry under 35 U.S.C. § 371 of International Application No. PCT/CN2023/135577, filed on Nov. 30, 2023, the entire content of which is incorporated herein by reference.

### TECHNICAL FIELD

The disclosure relates to the technology field of display device, in particular to a wiring substrate and a manufacturing method thereof, and an electronic apparatus.

### BACKGROUND

Miniature Light Emitting Diodes (LEDs) (such as Mini LEDs, Micro LEDs), due to the advantages such as smaller size, ultra-high brightness, and long life, are increasingly used in display products. In general, the miniature LEDs can be arranged on a printed circuit board (PCB) or glass substrate (Glass). The glass substrate has the characteristics of good thermal conductivity, high flatness, and low expansion coefficient, which can better support the packaging process of the miniature LEDs and ensure the packaging quality.

### SUMMARY

Embodiments of the disclosure provide a wiring substrate and a manufacturing method thereof, and an electronic apparatus. The specific solutions are as follows.

According to one aspect, the embodiments of the disclosure provide a wiring substrate, including a base substrate, a plurality of signal lines, and a plurality of connection lines. The base substrate includes a first surface and a second surface arranged oppositely. The second surface includes a bonding region extending in a first direction, and fan-out regions located on both sides of the bonding region in a second direction. The fan-out regions are provided with a plurality of vias. The first direction intersects the second direction. The plurality of signal lines are disposed on the first surface, and orthographic projections of the plurality of signal lines on the base substrate extend in the second direction, passing through the bonding region and the fan-out regions. The plurality of connection lines are disposed on the second surface, and extend from the fan-out regions to the bonding region. The connection lines are coupled with the signal lines through the plurality of vias.

In some embodiments, in the wiring substrate according to embodiments of the disclosure, the bonding region is located in a middle region of the second surface.

In some embodiments, in the wiring substrate according to embodiments of the disclosure, the fan-out regions on both sides of the bonding region are indicated as a first fan-out region and a second fan-out region, respectively. The plurality of connection lines include a constant voltage signal connection line and a common voltage signal connection line. The constant voltage signal connection line extends from the first fan-out region to the bonding region, and the common voltage signal connection line extends from the second fan-out region to the bonding region.

In some embodiments, in the wiring substrate according to embodiments of the disclosure, the constant voltage signal connection line includes a first constant voltage signal connection part extending in the second direction, and the common voltage signal connection line includes a first common voltage signal connection part extending in the second direction. The first constant voltage signal connection part extends from the first fan-out region to the bonding region, and the first common voltage signal connection part extends from the second fan-out region to the bonding region. The first common voltage signal connection part and the first constant voltage signal connection part are staggered in the first direction.

In some embodiments, in the wiring substrate according to embodiments of the disclosure, the plurality of signal lines include a plurality of constant voltage signal lines arranged in the first direction and extending in the second direction. The constant voltage signal connection line further includes a second constant voltage signal connection part integrally formed with the first constant voltage signal connection part. The second constant voltage signal connection part extends in the first direction within the first fan-out region, and is coupled with the plurality of constant voltage signal lines.

In some embodiments, in the wiring substrate according to embodiments of the disclosure, a line width of the second constant voltage signal connection part in the second direction is greater than or equal to 28 mm.

In some embodiments, in the wiring substrate according to embodiments of the disclosure, the plurality of connection lines include multiple connection line groups. The multiple connection line groups include multiple first connection line groups, which are located at a side of the first constant voltage signal connection part close to the first common voltage signal connection part, and at a side of the second constant voltage signal connection part close to the bonding region.

In some embodiments, in the wiring substrate according to embodiments of the disclosure, the first surface includes 2 n*2 m pad regions, where n and m are integers greater than 2. The plurality of signal lines include 2 m signal line groups arranged sequentially in the first direction. The signal line groups are located between adjacent constant voltage signal lines and pass through the pad regions in the second direction. An (m+1)-th signal line group to a 2m-th signal line group are coupled with the multiple first connection line groups in a (n-q)-th row of the pad regions, where q is an integer nearest to W1/W2 and greater than W1/W2, W1 indicates a size of the bonding region in the second direction, and W2 indicates a size of the pad region in the second direction.

In some embodiments, in the wiring substrate according to embodiments of the disclosure, the plurality of signal lines further include a plurality of common voltage signal lines extending in the second direction and arranged in the first direction. The common voltage signal connection line further includes a second common voltage signal connection part integrally formed with the first common voltage signal connection part. The second common voltage signal connection part extends in the first direction within the second fan-out region and is coupled with the plurality of common voltage signal lines.

In some embodiments, in the wiring substrate according to embodiments of the disclosure, a line width of the second common voltage signal connection part in the second direction is greater than or equal to 28 mm.

In some embodiments, in the wiring substrate according to embodiments of the disclosure, the plurality of connection lines further include multiple connection line groups. The multiple connection line groups include multiple second connection line groups, which are located at a side of the first common voltage signal connection part close to the first constant voltage signal connection part, and at a side of the second common voltage signal connection part close to the bonding region.

In some embodiments, in the wiring substrate according to embodiments of the disclosure, the first surface includes 2 n*2 m pad regions, where n and m are integers greater than 2. The plurality of signal lines include 2 m signal line groups arranged sequentially in the first direction and passing through the pad regions in the second direction. A first signal line group to an m-th signal line group are coupled to the multiple second connection line groups in a n-th row of pad regions.

In some embodiments, in the wiring substrate according to embodiments of the disclosure, the signal line group includes an address signal line, a power signal line and a feedback signal line, and the connection line group includes an address signal connection line, a power signal connection line and a feedback signal connection line. The address signal connection line is coupled with the address signal line, the power signal connection line is coupled with the power signal line, the feedback signal connection line is coupled with the feedback signal line. In a 2n-th row of pad regions, the address signal line and the feedback signal line of a same signal line group are integrally formed.

In some embodiments, in the wiring substrate according to embodiments of the disclosure, a line width of the address signal connection line is greater than or equal to 0.1 mm, a line width of the power signal connection line is greater than or equal to 0.2 mm, and a line width of the feedback signal connection line is greater than or equal to 0.1 mm.

In some embodiments, in the wiring substrate according to embodiments of the disclosure, the first surface includes 2 n*2 m pad regions, and n and m are integers greater than 2. The pad region is provided with a first pad group and a second pad group, and the first pad group includes at least two sub-pad groups. In at least a 2n-th row pad regions, the second pad group is located between adjacent sub-pad groups.

In some embodiments, the wiring substrate according to embodiments of the disclosure, further includes an insulating layer on a side of the plurality of connection lines away from the base substrate. The insulating layer includes multiple openings in the bonding region, and within the bonding region, orthographic projections of the plurality of connection lines on the base substrate are located within orthographic projections of the multiple openings on the base substrate.

According to another aspect, embodiments of the disclosure provide an electronic apparatus, including at least one wiring substrate according to embodiments of the disclosure and a plurality of light-emitting structures coupled with the plurality of signal lines.

In some embodiments, in the electronic apparatus according to embodiments of the disclosure, the first surface includes a plurality of pad regions. The pad region is provided with a first pad group and a second pad group. The light-emitting structure includes an electronic component coupled with the first pad group and a micro drive chip coupled with the second pad group.

In some embodiments, the electronic apparatus according to embodiments of the disclosure, further includes a drive circuit board. The drive circuit board is coupled with the plurality of connection lines in the bonding region.

In some embodiments, in the electronic apparatus according to embodiments of the disclosure, the drive circuit board includes a chip-on-film (COF).

According to another aspect, embodiments of the disclosure provide a manufacturing method for a wiring substrate, including:
providing a base substrate; where the base substrate includes a first surface and a second surface arranged oppositely, the second surface includes a bonding region extending in a first direction and fan-out regions located on both sides of the bonding region in a second direction, and the first direction intersects the second direction;
forming a plurality of vias at predetermined positions in the fan-out regions, where the plurality of vias pass through the base substrate in a direction perpendicular to the first surface and the second surface;
forming a plurality of signal lines on the first surface; where orthographic projections of the plurality of signal lines on the base substrate extend in the second direction, passing through the bonding region and the fan-out regions;
forming a plurality of connection lines, extending from the fan-out regions to the bonding region, on the second surface, in such a way that the plurality of connection lines are coupled with the plurality of signal lines through the plurality of vias.

### BRIEF DESCRIPTION OF FIGURES

FIG. 1 is a schematic structural diagram of a wiring substrate in the related art.

FIG. 2 is a schematic structural diagram of a wiring substrate according to embodiments of the disclosure.

FIG. 3 is a schematic diagram illustrating wiring layout on a first surface of the wiring substrate shown in FIG. 2.

FIG. 4 is a schematic diagram illustrating wiring layout on a second surface of the wiring substrate shown in FIG. 2.

FIG. 5 is a schematic diagram combining a cross-sectional view along line I-II and a cross-sectional view along line III-IV shown in FIG. 2.

FIG. 6 is schematic diagram illustrating structural division of the wiring substrate according to embodiments of the disclosure.

FIG. 7 is a schematic diagram illustrating current flow in one pad region PA of the wiring substrate according to embodiments of the disclosure.

FIG. 8 illustrates an enlarged view of region Z1 shown in FIG. 3.

FIG. 9 illustrates an enlarged view of region Z2 shown in FIG. 3.

FIG. 10 illustrates an enlarged view of region Z3 shown in FIG. 3.

FIG. 11 illustrates an enlarged view of region Z4 shown in FIG. 8.

FIG. 12 illustrates an enlarged view of region Z5 shown in FIG. 9.

FIG. 13 illustrates an enlarged view of region Z6 shown in FIG. 10.

FIG. 14 is a schematic structural diagram of an electronic apparatus according to embodiments of the disclosure.

FIG. 15 is another schematic structural diagram of an electronic apparatus according to embodiments of the disclosure.

FIG. 16 is a schematic structural diagram of a first surface of the electronic apparatus shown in FIG. 15.

FIG. 17 illustrates an enlarged view of a region Z7 shown in FIG. 16.

FIG. 18 is a schematic structural diagram of a micro drive chip according to embodiments of the disclosure.

FIG. 19 is a schematic structural diagram of a second surface of the electronic apparatus shown in FIG. 15.

FIG. 20 shows schematic flowchart of a manufacturing method of a wiring substrate according to embodiments of the disclosure.

FIG. 21 is a schematic diagram illustrating a flow of manufacturing vias and filling vias.

### DETAILED DESCRIPTION

To make the objectives, technical solutions, and advantages of embodiments of the disclosure clearer, the technical solutions of the embodiments of the disclosure will be clearly and completely described below in conjunction with the accompanying drawings. It should be noted that, to make the objectives, in the accompanying drawings, the thicknesses of layers, films, panels, regions, etc., are exaggerated for clarity. The exemplary embodiments are described with reference to cross-sectional views, which are schematic diagrams of idealized implementations. As such, deviations in shape resulting from manufacturing techniques and/or tolerances are expected. Therefore, the embodiments described in the disclosure should not be interpreted as limited to the specific shapes of the regions illustrated in the disclosure, but should include deviations in shape resulting from manufacturing. For example, regions depicted or described as flat may typically have rough and/or non-linear features; sharp corners illustrated may be rounded, etc. Thus, the regions shown in the figures are essentially schematic, and their dimensions and shapes are not intended to illustrate the precise shapes of the regions, nor do they reflect true proportions, but rather serve to illustrate the content of the disclosure. Furthermore, the same or similar reference numerals are used throughout to denote the same or similar elements or elements with the same or similar functions. To keep the following description of the embodiments clear and concise, detailed descriptions of known functions and known components are omitted.

Unless otherwise defined, technical terms or scientific terms used herein should have the usual meaning understood by those skilled in the art to which the disclosure belongs. The terms “first,” “second,” and similar words used in the description and claims of the disclosure do not indicate any sequence, quantity, or importance, but are merely used to distinguish different components. Words such as “comprise” or “include” indicate that the elements or objects appearing before the word cover the elements or objects listed after the word and their equivalents, without excluding other elements or objects. Words such as “connected” or “coupled” are not limited to physical or mechanical connections but may include electrical connections, whether direct or indirect. Terms like “inner,” “outer,” “upper,” “lower,” etc., are used only to indicate relative positional relationships, which may change correspondingly if the absolute position of a described object changes.

In the following description, when an element or layer is described as being “on” or “connected with” another element or layer, it can be directly on or connected with the other element or layer, or there may be intervening elements or layers. When an element or layer is described as being “on one side of” another element or layer, it can be directly on one side of the other element or layer, directly connected with the other element or layer, or there may be intervening elements or layers. However, when an element or layer is described as being “directly on” another element or layer or “directly connected with” another element or layer, there are no intervening elements or layers. The term “and/or” includes any and all combinations of one or more of the associated listed items.

In recent years, the advantages of glass substrates have become increasingly prominent in the field of new display technologies. Compared with printed circuit boards, glass substrates have better thermal conductivity, higher flatness, and lower expansion coefficient, making them better suited for chip-on-board (COB) packaging of micro LEDs. This avoids a potential problem of adhesive cracking due to differences in thermal expansion coefficients between the sealing adhesive and the printed circuit board material. Moreover, in high-precision backlight partitioning, glass substrates enable narrow bezels and low optical distance (OD) (a distance between the lower surface of the diffuser and the upper surface of the circuit board), allowing products to be thinner and more stylish. Additionally, the backplane area of a glass substrate can be made larger as needed, achieving unlimited splicing at relatively lower costs and exhibiting excellent high-frequency electrical characteristics.

Glass is an insulating material with a dielectric constant only about one-third of that of silicon, and its loss factor is 2 to 3 orders of magnitude lower than that of silicon. This greatly reduces substrate loss and parasitic effects, ensuring the integrity of signal transmission. Large-size ultra-thin glass substrates are easy to obtain. For example, relevant glass manufacturers can provide ultra-large size (>2 m*2 m) and ultra-thin (<50 μm) panel glass as well as ultra-thin flexible glass materials. Thanks to the easy availability of large-size ultra-thin panel glass and the absence of the need to deposit an insulating layer, the manufacturing cost of glass-based transfer plate is approximately one-eighth that of silicon-based transfer plate. Furthermore, even when the thickness of the glass-based transfer is less than 100 μm, warpage is still minimal, demonstrating good mechanical stability.

Micro LED display technology combines many advantages of liquid crystal display (LCD) technology and organic light-emitting display (OLED) technology. When applied to backlighting, Micro LED display technology can achieve more precise dynamic backlight effects, effectively improving screen brightness and contrast while also solving the glare phenomenon caused by traditional dynamic backlighting between bright and dark areas on the screen. This optimizes the visual experience and is more suitable for ultra-large screen products.

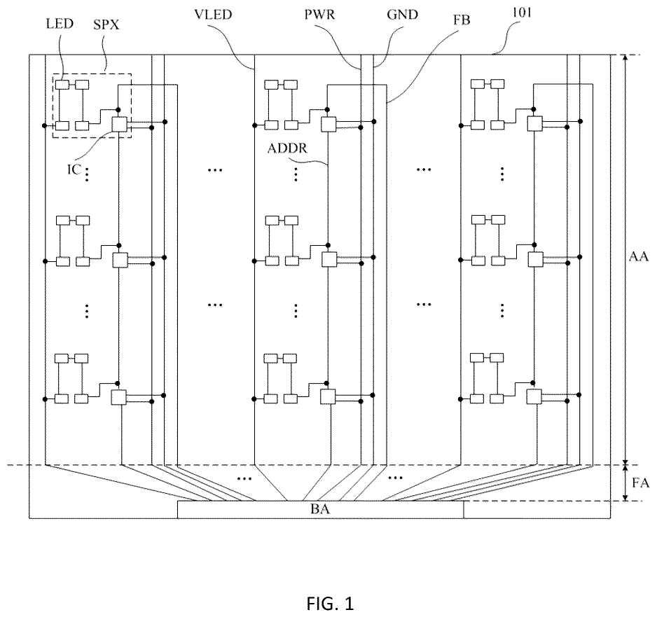

FIG. 1 is a schematic structural diagram of an electronic apparatus in the related art. As shown in FIG. 1, the electronic apparatus includes a light-emitting region AA, a fan-out region FA, and a bonding region BA, arranged sequentially along a longitudinal direction. The light-emitting region AA is provided with multiple sub-pixels SPX arranged in an array, each sub-pixel SPX including multiple LEDs (such as mini LEDs, Micro LEDs, etc.) and a micro drive chip (IC). Each column of sub-pixels SPX is coupled with a signal line group. Each signal line group, the LEDs and micro drive chips (IC) all are arranged on the same side of the base substrate 101. One signal line group includes a constant voltage signal line (VLED), an address signal line (ADDR), a power signal line (PWR), a common voltage signal line (GND), and a feedback signal line (FB). These signal lines extend from the light-emitting region AA to the fan-out region FA, then are coupled with the drive circuit in the bonding region BA (e.g., a chip-on-film (COF)). However, the fan-out region FA and bonding region BA occupy a relatively large space, resulting in a wider lower bezel, which is unfavorable for splicing required by the large-size electronic apparatus.

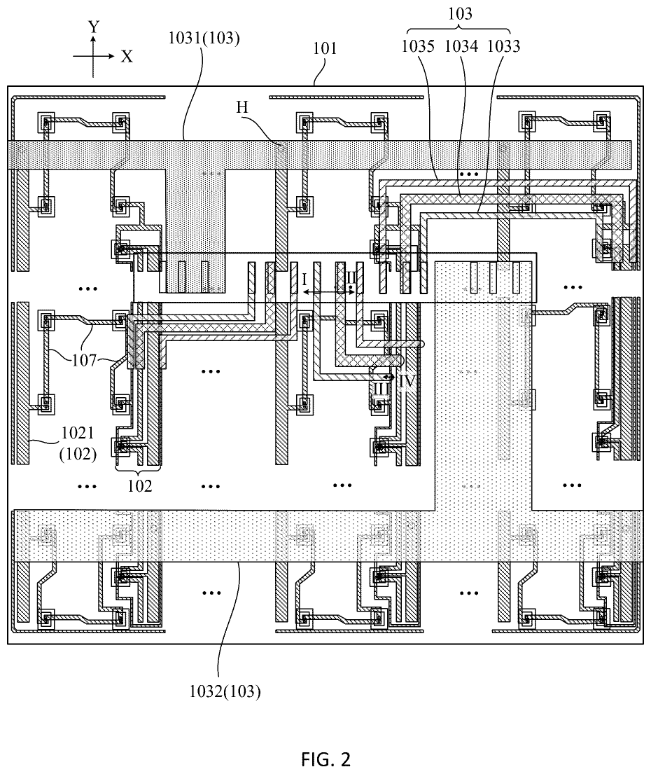

To address at least the technical issues existing in the related art, embodiments of the disclosure provide a wiring substrate, as shown in FIGS. 2 to 5, including: a base substrate 101, a plurality of signal lines 102, and a plurality of connection lines 103.

The base substrate 101 includes a first surface S1 and a second surface S2 that are oppositely arranged. The second surface S2 includes a bonding region BA extending in the first direction X, and fan-out regions FA on both sides of the bonding region BA in the second direction Y. The fan-out region FA is provided with a plurality of vias H. The first direction X intersects the second direction Y. In some embodiments, the base substrate 101 can be a substrate that allows visible light to pass through, such as glass, quartz, or plastic.

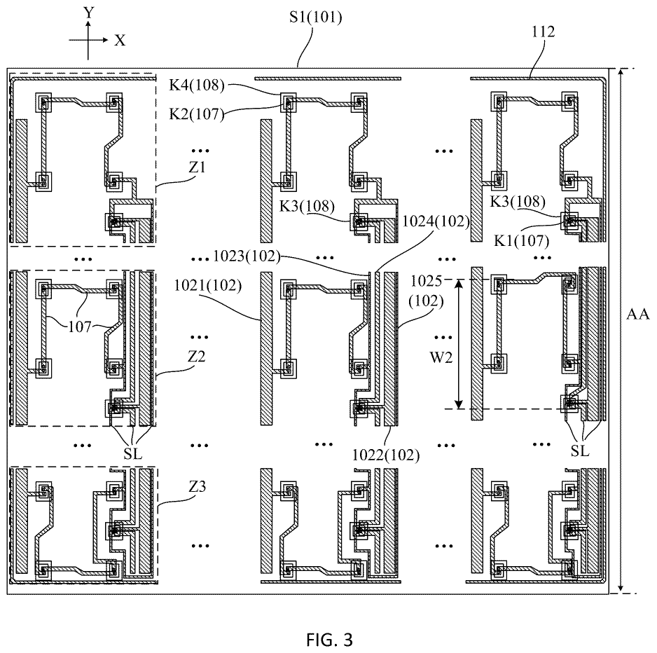

The plurality of signal lines 102 are disposed on the first surface S1. Orthographic projections of the plurality of signal lines 102 on the base substrate 101 extend along the second direction Y and pass through the bonding region BA and the fan-out region FA. As shown in FIG. 3, the first surface S1 includes only the light-emitting region AA. Optionally, the material of signal lines 102 includes, but is not limited to, metals such as copper (Cu).

The plurality of connection lines 103 are disposed on the second surface S2. The plurality of connection lines 103 extend from the fan-out region FA to the bonding region BA, and are electrically connected with the plurality of signal lines 102 through multiple vias H in the fan-out region FA. Optionally, the material of connection lines 103 includes, but is not limited to, metals such as copper (Cu).

In the wiring substrate according to embodiments of the disclosure, the plurality of signal lines 102 of the light-emitting region AA are arranged on the first surface S1 of the base substrate 101 and arranging the fan-out region FA and bonding region BA to the second surface S2, while the plurality of connection lines 103 are disposed on the second surface S2, and electrical connection between connection lines 103 and signal lines 102 are realized through vias H passing through the base substrate 101, so that the driving circuits in the bonding region BA (e.g., chip-on-film (COF)) can load driving signals onto the signal lines 102 via the connection lines 103. By moving the fan-out region FA and bonding region BA from the lower bezel to the opposite side of the light-emitting region AA, a width of the lower bezel of the base substrate 101 can be reduced, which is beneficial for splicing required for large-size display panels.

Additionally, compared to wiring connection lines 103 on one side of the bonding region BA, in the disclosure, fan-out regions FA on both sides of the bonding region BA on the second surface S2 are provided and connection lines 103 are provided in both fan-out regions FA, ensuring ample wiring space in both fan-out regions FA. This allows for increasing the width of connection lines 103, reducing the thickness of the layer where connection lines 103 are located, decreasing resistance, and improving signal uniformity. Moreover, wider connection lines 103 can achieve better heat dissipation. Furthermore, the copper proportion is increased in the copper processing process, which reduces the etching portion, thereby lowering the etching solution consumption and reducing the cost of the etching process.

In addition, for large-size products, to ensure signal uniformity, the light-emitting region AA needs to be divided into multiple zones, with multiple driving circuits (e.g., 8 chip-on-film (COF)) providing driving signals to the signal lines 102 in each zone. In the disclosure, due to the ample wiring space in both fan-out regions FA, the resistance can be reduced by increasing the width of connection lines 103, thereby improving signal uniformity. As a result, one driving circuit (e.g., 1 chip-on-film (COF)) can be used to load driving signals onto all signal lines 102 in large-size products. As such, the solution of the disclosure can save 7 driving circuits (e.g., 7 chip-on-film (COF)) compared to related art, leading to significant economic benefits in mass production, with easier connection and assembly.

In some embodiments, to ensure a clean and non-short-circuiting wiring layout, in the related art, the constant voltage signal lines (VLED), address signal lines (ADDR), power signal lines (PWR), common voltage signal lines (GND), and feedback signal lines (FB), as well as the corresponding fan-out lines are arranged at the same side and in the two conductive layers, i.e., a single-sided double-layer copper process is used to form constant voltage signal lines (VLED), address signal lines (ADDR), power signal lines (PWR), common voltage signal lines (GND), feedback signal lines (FB), and the corresponding fan-out lines. In the disclosure, all signal lines 102 (including constant voltage signal lines, address signal lines, power signal lines, common voltage signal lines, and feedback signal lines) can be arranged in the same layer and can be formed using the same material at the side of the first surface S1, and all connection lines 103 can be arranged in the same layer and can be formed using the same material at the side of the second surface S2. That is, a single-sided single-layer copper process can be used to complete the manufacturing of all signal lines 102 and all connection lines 103. The single-sided single-layer copper process is simpler and have higher yields compared to the single-sided double-layer copper process.

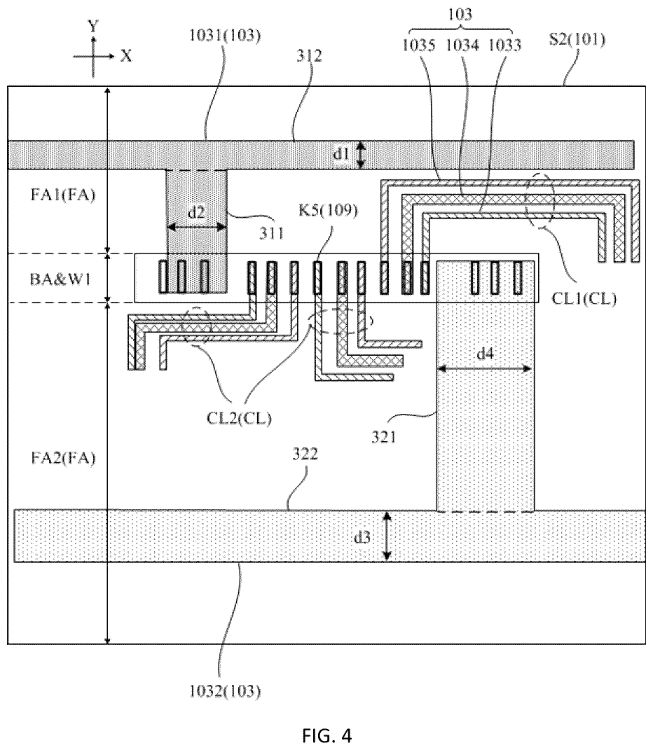

In some embodiments, in the wiring substrate according to embodiments of the disclosure, as shown in FIGS. 2 and 4, the bonding region BA can be set in the middle region of the second surface S2, so that there is ample wiring space in both fan-out regions FA on each side of the bonding region BA. This allows for wider connection lines 103 dispersed in the fan-out region FA, reducing resistance and improving signal uniformity. It should be noted that the “middle region of the second surface S2” can be understood as the region near a central axis along the first direction X of the second surface S2. For example, the regions covering approximately two rows of sub-pixels SPX along the second direction Y from the central axis along the first direction X, of the second surface S2. For example, if there are 24 rows of sub-pixels SPX along the second direction Y, the middle region of the second surface S2 could be the region from the 10th row of sub-pixels SPX to the 14th row of sub-pixels SPX.

In some embodiments, in the wiring substrate according to embodiments of the disclosure, as shown in FIGS. 2 to 4, the fan-out regions FA on both sides of the bonding region BA are referred to as a first fan-out region FA1 and a second fan-out region FA2. The plurality of connection lines 103 include a constant voltage signal connection line 1031 and common voltage signal connection line 1032. The constant voltage signal connection line 1031 is coupled with a plurality of constant voltage signal lines 1021 extending in the second direction Y and arranged in the first direction X, and the constant voltage signal connection line 1031 extends from the first fan-out region FA1 to the bonding region BA. The common voltage signal connection line 1032 is coupled with a plurality of common voltage signal lines 1022 extending in the second direction Y and arranged in the first direction X, and the common voltage signal connection line 1032 extends from the second fan-out region FA2 to the bonding region BA.

The constant voltage signal connection line 1031 extends from the first fan-out region FA1 on one side of the bonding area BA to the bonding area BA, and the common voltage signal connection line 1032 extends from the second fan-out region FA2 on the other side of the bonding area BA to the bonding area BA, which is beneficial to ensure that both the constant voltage signal connection line 1031 and the common voltage signal connection line 1032 have a larger line width (e.g., greater than or equal to 28 mm). This reduces the resistance of the constant voltage signal connection line 1031 and the common voltage signal connection line 1032, thereby decreasing the voltage difference provided by the constant voltage signal connection line 1031 to the plurality of constant voltage signal lines 1021, and reducing the common voltage signal difference provided by the common voltage signal connection line 1032 to the plurality of common voltage signal lines 1022. Additionally, the constant voltage signal connection line 1031 and the common voltage signal connection line 1032, with the larger line width, on both sides of the bonding area BA ensure that the pattern density on both sides of the bonding area BA is similar, which helps improve the etching effect.

In some embodiments, in the wiring substrate according to embodiments of the disclosure, as shown in FIGS. 2 to 4, the constant voltage signal connection line 1031 includes a first constant voltage signal connection part 311 extending in the second direction Y, and the common voltage signal connection line 1032 includes a first common voltage signal connection part 321 extending in the second direction Y. The first constant voltage signal connection part 311 extends from the first fan-out region FA1 to the bonding area BA, and the first common voltage signal connection part 321 extends from the second fan-out region FA2 to the bonding area BA. In some embodiments, to ensure a simple wiring layout without short-circuiting, the first common voltage signal connection part 321 and the first constant voltage signal connection part 311 can be staggered along the first direction X.

In some embodiments, in the wiring substrate according to embodiments of the disclosure, as shown in FIGS. 2 to 4, the constant voltage signal connection line 1031 can further include a second constant voltage signal connection part 312 integrally arranged with the first constant voltage signal connection part 311. The second constant voltage signal connection part 312 extends within the first fan-out region FA1 along the first direction X and is coupled to the plurality of constant voltage signal lines 1021. Optionally, the second constant voltage signal connection part 312 is coupled to the plurality of constant voltage signal lines 1021 within a region where the first row of sub-pixels SPX is located. Optionally, to ensure a low resistance of the second constant voltage signal connection part 312, a line width d1, in the second direction Y, of the second constant voltage signal connection part 312 can be set to be greater than or equal to 28 mm. In some embodiments, if wiring space is sufficient, the line width d2 of the first constant voltage signal connection part 311 along the first direction X can be set to be greater than or equal to the line width d1 of the second constant voltage signal connection part 312 along the second direction Y, for example, the line width d2 of the first constant voltage signal connection part 311 along the first direction X can be greater than or equal to 28 mm. In cases where wiring space is limited, the line width d2 of the first constant voltage signal connection part 311 along the first direction X can be set to be less than the line width d1 of the second constant voltage signal connection part 312 along the second direction Y, for example, the line width d2 of the first constant voltage signal connection part 311 along the first direction X can be less than 28 mm. The disclosure does not impose specific limitations on this.

In some embodiments, in the wiring substrate according to embodiments of the disclosure, as shown in FIGS. 2 to 4, the plurality of connection lines 103 can further include a plurality of connection line groups CL. The plurality of connection line groups CL include multiple first connection line groups CL1, and the multiple first connection line groups CL1 are located at the side of the first constant voltage signal connection part 311 near the first common voltage signal connection part 321 and at the side of the second constant voltage signal connection part 312 near the bonding area BA. That is, the multiple first connection line groups CL1 are arranged in the region surrounded by the first constant voltage signal connection part 311, the second constant voltage signal connection part 312, and the bonding area BA, with the region close to the first common voltage signal connection part 321. In this region, there is more wiring space, which facilitates flexible layout of the multiple first connection line groups CL1.

In some embodiments, in the wiring substrate according to embodiments of the disclosure, as shown in FIGS. 2 to 4 and FIG. 6, the first surface S1 includes 2 n*2 m pad regions PA. One pad region PA can be coupled to multiple light-emitting diodes (LEDs) and one micro-drive chip (IC) to form a region of one sub-pixel SPX. Both n and m are integers greater than 2, for example, n can be 12 and m can be 24. Optionally, the plurality of signal lines 102 further include 2 m signal line groups SL arranged sequentially along the first direction X. The signal line groups SL are located between adjacent constant voltage signal lines 1021 and extend through the pad regions PA in the second direction Y. Here, the (m+1)-th signal line group to the 2m-th signal line group is coupled to the multiple first connection line groups CL1 in the (n-q)-th row of the pad regions PA. Optionally, each signal line group from the (m+1)-th signal line group to the 2m-th signal line group is coupled to each of the multiple first connection line groups CL1 one-to-one. Here, q is an integer nearest to W1/W2 and greater than W1/W2, where W1 indicates a size of the bonding area BA in the second direction Y, and W2 indicates a size of the pad region PA in the second direction Y.

Since the n-th row of pad regions PA is centered on the first surface S1, and the (n-q)-th row of pad regions PA is offset by the width of a bonding area BA from the n-th row of pad regions PA, the (n-q)-th row of pad regions PA can be considered to be located in the middle region of the first surface S1. Based on this, the (m+1)-th signal line group to the 2m-th signal line group are coupled to the multiple first connection line groups CL1 in the (n-q)-th row of pad regions PA, allowing the driving signals, provided by the first connection line groups CL1 to the (m+1)th to the 2mth signal line groups, to transmit from the (n-q)-th row of pad regions PA simultaneously to both the first row of pad regions PA and the last row of pad regions PA, reducing the differences in driving signals of the respective rows of pad regions PA caused by line resistance and improving signal uniformity.

In some embodiments, in the wiring substrate according to embodiments of the disclosure, as shown in FIGS. 2 to 4, the common voltage signal connection line 1032 can further include a second common voltage signal connection part 322 integrally arranged with the first common voltage signal connection part 321. The second common voltage signal connection part 322 extends within the second fan-out region FA2 along the first direction X and is coupled to the plurality of common voltage signal lines 1022. Optionally, the second common voltage signal connection part 322 is coupled to the plurality of common voltage signal lines 1022 in a region where the last row of sub-pixels SPX is located. To ensure a low resistance of the second common voltage signal connection part 322, a line width d3 of the second common voltage signal connection part 322 in the second direction Y can be set to be greater than or equal to 28 mm. In some embodiments, if wiring space is sufficient, the line width d4 of the first common voltage signal connection part 321 along the first direction X can be set to be greater than or equal to the line width d3 of the second common voltage signal connection part 322 along the second direction Y, for example, the line width d4 of the first common voltage signal connection part 321 along the first direction X can be greater than or equal to 28 mm. In cases where wiring space is limited, the line width d4 of the first common voltage signal connection part 321 along the first direction X can be set to be less than the line width d3 of the second common voltage signal connection part 322 along the second direction Y, for example, the line width d4 of the first common voltage signal connection part 321 along the first direction X can be less than 28 mm. The disclosure does not impose specific limitations on this.

In some embodiments, as shown in FIGS. 2 to 4, the plurality of connection line groups CL may further include multiple second connection line groups CL2. The multiple second connection line groups CL2 are located at the side of the first common voltage signal connection part 321 near the first constant voltage signal connection part 311 and at the side of the second common voltage signal connection part 322 near the bonding area BA. In other words, the multiple second connection line groups CL2 are arranged in the region surrounded by the first common voltage signal connection part 321, the second common voltage signal connection part 322, and the bonding area BA, with the region close to the first constant voltage signal connection part 311. This region has a larger wiring space, facilitating the flexible layout of multiple second connection line groups CL2. Moreover, the multiple first connection line groups CL1 and the multiple second connection line groups CL2 are separated at both sides of the bonding area BA, effectively ensuring that the pattern density at both sides of the bonding area BA is similar, which helps to improve the etching effect.

In some embodiments, in the wiring substrate according to embodiments of the disclosure, as shown in FIGS. 2 to 4 and 6, the first signal line group to the m-th signal line group are coupled to the multiple second connection line groups CL2 in the n-th row of pad regions. Optionally, each signal line group from the first signal line group to the m-th signal line group is coupled one-to-one with each of the multiple second connection line groups CL2. Since the n-th row of pad regions PA is centered in the first surface S1, the first signal line group to the m-th signal line group are coupled with multiple second connection line groups CL2 in the n-th row of pad regions PA, allowing driving signals, provided by the second connection line groups CL2 to the first signal line group to the m-th signal line group, to transmit from the n-th row of pad regions PA simultaneously to the first row and the last row of pad regions PA. This reduces the differences in driving signals among the rows of pad regions PA caused by line resistance and improves signal uniformity.

In some embodiments, in the wiring substrate according to embodiments of the disclosure, as shown in FIGS. 2 to 4, the signal line groups SL include address signal lines 1023, power signal lines 1024, and feedback signal lines 1025. The connection line groups CL include address signal connection line 1033, power signal connection line 1034, and feedback signal connection line 1035. The address signal connection line 1033 is coupled to the address signal lines 1023, the power signal connection line 1034 is coupled to the power signal lines 1024, and the feedback signal connection line 1035 is coupled to the feedback signal lines 1025. In the 2n-th row of pad regions PA (i.e., the last row of pad regions PA), the address signal line 1023 and the feedback signal line 1025 within the same signal line group SL are integrally formed to form a current loop within a same column of pad regions PA.

In some embodiments, to ensure signal uniformity, the line width of the address signal connection line 1033 can be set to be greater than or equal to 0.1 mm, the line width of the power signal connection line 1034 can be set to be greater than or equal to 0.2 mm, and the line width of the feedback signal connection line 1035 can be set to be greater than or equal to 0.1 mm. It should be understood that the maximum line width of the address signal connection line 1033, power signal connection line 1034, and feedback signal connection line 1035 can be set according to the manufacturing process precision and wiring space, which is not limited here.

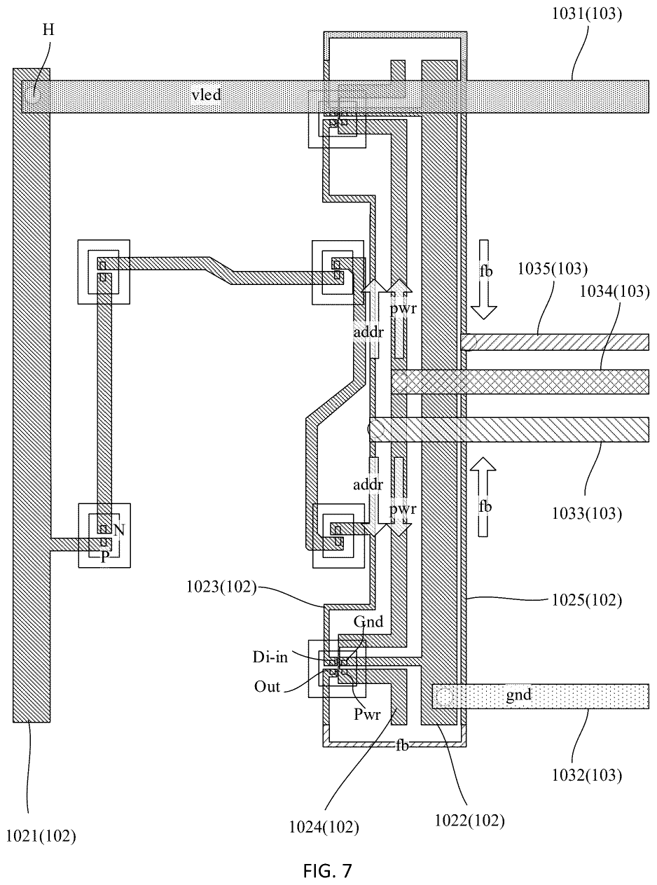

To better understand the current direction in the disclosure, an example with a wiring substrate having 24*48 pad regions PA will be explained. As shown in FIGS. 6 and 7, the 24*48 pad regions PA are divided into left and right halves. For the left half-screen: in the pad regions PA in 1st to 24th columns and first to 12th rows, address signals addr and power signals pwr flow into the 12th row of pad regions PA and flow out from the 1st row of pad regions PA, while feedback signals fb flow from the 1st row of pad regions PA to the 12th row of pad regions PA. In the pad regions PA in the 1st to 24th columns and 13th to 24th rows, address signals addr and power signals pwr flow into the 13th row of pad regions PA and flow out from the 24th row of pad regions PA, while feedback signals fb flow from the 24th row of pad regions PA to the 13th row of pad regions PA. For the right half-screen: in the pad regions PA in 25th to 48th columns and 1st to 10th rows, address signals addr and power signals pwr flow into the 10th row of pad regions PA and out of the 1st row of pad regions PA, while feedback signals fb flow from the 1st row of pad regions PA to the 10th row of pad regions PA. In the pad regions PA in 25th to 48th columns and 11th to 24th rows, address signals addr and power signals pwr flow into the 10th row of pad regions PA and out of the 24th row of pad regions PA, while feedback signals fb flow from the 24th row of pad regions PA to the 10th row of pad regions PA. Additionally, for both the left and right half-screens, the constant voltage signals vled flow from the 1st row of pad regions PA to the 24th row of pad regions PA, and the common voltage signal gnd flows from the 24th row of pad regions PA to the 1st row of pad regions PA.

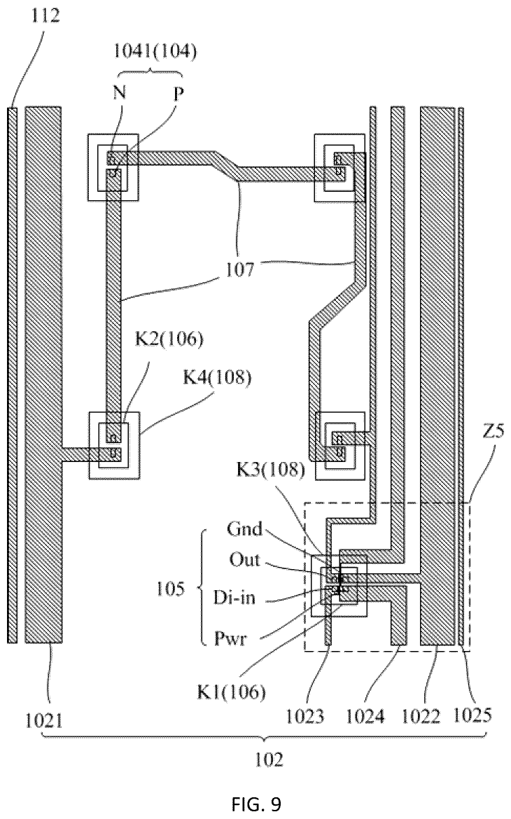

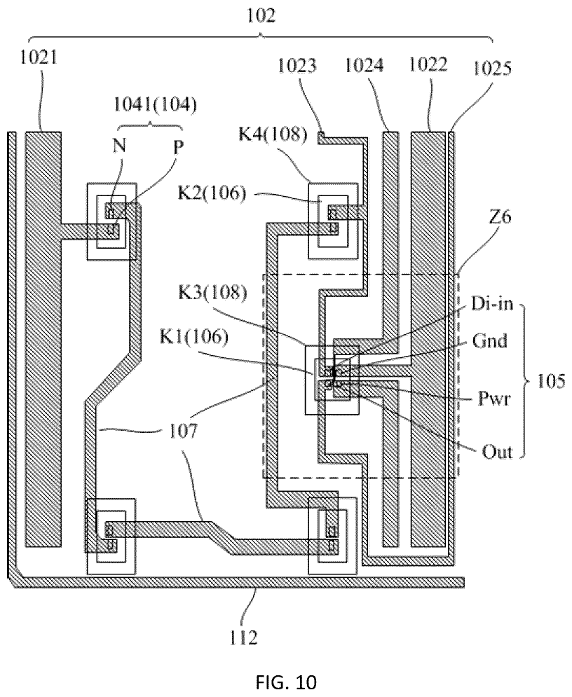

In some embodiments, in the wiring substrate according to embodiments of the disclosure, as shown in FIGS. 2, 3, 8 to 10, the pad region PA is provided with a first pad group 104 and a second pad group 105. The first pad group 104 includes at least two sub-pad groups 1041. Optionally, at least two sub-pad groups 1041 within the same first pad group 104 can be connected in series, parallel, or a combination of series and parallel. In some embodiments, to further reduce the lower bezel width, in at least the 2n-th row of pad regions PA (i.e., last row of pad regions PA), the second pad group 105 can be positioned between adjacent sub-pad groups 1041. For example, in FIG. 10, the second pad group 105 is located between two adjacent sub-pad groups 1041 on the right side. Of course, in some embodiments, the second pad group 105 can be located in the center of the region surrounded by four sub-pad groups 1041, which is not limited here. As shown in FIGS. 2, 3, 8, and 9, in the first to (2n-1)-th row of pad regions PA, the second pad group 105 can be located at the side of the first pad group 104 close to the next row of pad regions PA.

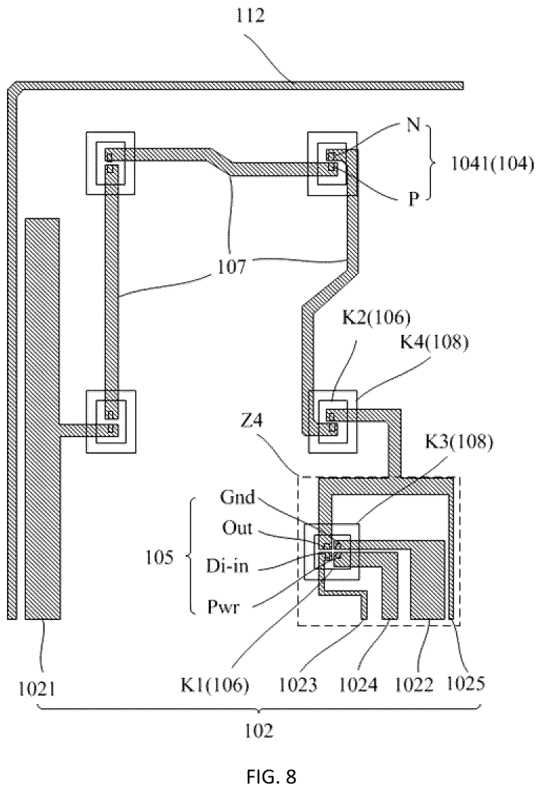

In some embodiments, as shown in FIGS. 8 to 10, a sub-pad group 1041 can include a first pad P and a second pad N, with the first pad P and the second pad N coupled to the positive and negative terminals of an LED, respectively.

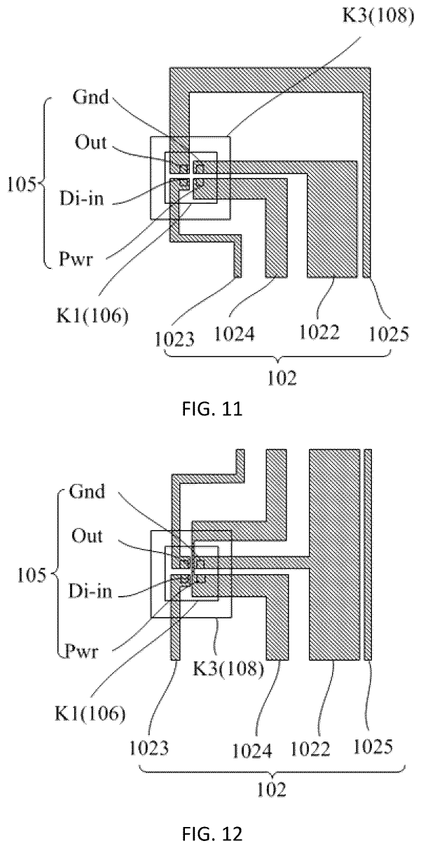

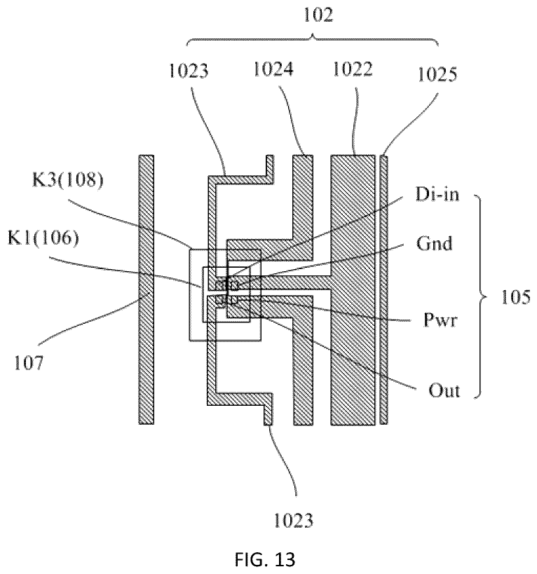

In some embodiments, as shown in FIGS. 11 to 13, the second pad group 105 can include an output pad Out, an address pad Di-in, a power pad Pwr, and a ground pad Gnd. As shown in FIGS. 11 and 12, in the first to (2n-1)-th row of pad regions PA, the address pad Di-in and the power pad Pwr of the same second pad group 105 are spaced apart in the first direction X and spaced apart from the output pad Out in the second direction Y. The ground pad Gnd and the power pad Pwr are spaced apart in the second direction Y and spaced apart from the output pad Out in the first direction X. For example, the output pad Out is located in the top left corner of the second pad group 105, the address pad Di-in is located in the bottom left corner, the ground pad Gnd is located in the top right corner, and the power pad Pwr is located in the bottom right corner. As shown in FIG. 13, in the 2n-th row of pad regions PA, the address pad Di-in and the ground pad Gnd of the same second pad group 105 are spaced apart in the first direction X and spaced apart from the output pad Out in the second direction Y. The power pad Pwr and the ground pad Gnd are spaced apart in the second direction Y and spaced apart from the output pad Out in the first direction X. For example, the output pad Out is located in the bottom left corner of the second pad group 105, the address pad Di-in is located in the top left corner, the ground pad Gnd is located in the top right corner, and the power pad Pwr is located in the bottom right corner.

In some embodiments, each second pad group 105 can be coupled with a micro-drive chip (IC). The address pad Di-in can receive address signals for gating the micro-drive chip (IC) with the corresponding address. The power pad Pwr can provide operating voltage and communication data to the micro-drive chip (IC), with the communication data configured to control the operating state of the corresponding LED. The output pad Out can output relay signals and driving signals during different periods. Optionally, the relay signal is an address signal provided to the address pad Di-in in the second pad group 105 of the next row in the same column, and the driving signal is a driving current configured to drive the LED coupled with the second pad group 105 including the output pad Out. The ground pad Gnd receives the common voltage signal.

In some embodiments, as shown in FIGS. 8 to 13, the wiring substrate according to embodiments of the disclosure may further include a first insulating layer 106 on the side of the plurality of signal lines 102 away from the base substrate 101. Optionally, the material of the first insulating layer 106 can be silicon oxide (SiOx), silicon nitride (SiNx), silicon oxynitride (SiON), aluminum oxide (AIOx), hafnium oxide (HfOx), tantalum oxide (TaOx), etc. The first insulating layer 106 can be a single-layer or multi-layer structure, for example, the first insulating layer 106 may include a stack of silicon nitride layer and silicon oxide layer. The first insulating layer 106 may have multiple first openings K1. The first openings K1 may expose portions of the common voltage signal line 1022 as ground pads Gnd, expose portions of the power signal line 1024 as power pads Pwr, expose portions of the address signal line 1023 in the last row pad regions PA as address pads Di-in, and expose both ends of the address signal line 1023 connecting with adjacent two rows of pad regions PA as address pads Di-in in the previous rows pad regions PA and out pads Out in the next row of pad regions PA. Additionally, as shown in FIGS. 8 to 10, the wiring substrate may further have multiple routing lines 107 that are in the same layer and made of the same material as the signal lines 102. The first insulating layer 106 may further include multiple second openings K2, and the second openings K2 expose portions of the routing lines 107 as the first pads P and the second pads N.

In some embodiments, as illustrated in FIGS. 8 to 13, the wiring substrate according to embodiments of the disclosure may further include a reflecting layer 108 on the side of the first insulating layer 106 away from the base substrate 101. For example, an insulating reflective material such as white oil may be used to coat the first insulating layer 106 to form the reflecting layer 108. The reflecting layer 108 includes multiple third openings K3 for exposing the second pad groups 105 and multiple fourth openings K4 for exposing the sub-pad groups 1041. The reflecting layer 108 is configured to reflect incident light towards the light-emitting side of the wiring substrate, thereby improving the utilization of the light emitted by the LED.

In some embodiments, as shown in FIG. 4, the wiring substrate according to embodiments of the disclosure may further include a second insulating layer 109 on the side of the plurality of connection lines 103 away from the base substrate 101. The material of the second insulating layer 109 can be silicon oxide (SiOx), silicon nitride (SiNx), silicon oxynitride (SiON), aluminum oxide (ALOx), hafnium oxide (HfOx), tantalum oxide (TaOx), etc. The second insulating layer 109 can be a single-layer or multi-layer structure, for example, the second insulating layer 109 may include a stack of silicon nitride layer and silicon oxide layer. Optionally, the second insulating layer 109 includes multiple fifth openings K5 in the bonding area BA. In the bonding area BA, the orthographic projections of multiple connection lines 103 on the base substrate 101 is within the orthographic projections of the multiple fifth openings K5 on the base substrate 101, allowing the multiple fifth openings K5 to expose portions of the multiple connection lines 103 in the bonding area BA, facilitating subsequent electrical connection between the multiple connection lines 103 and the driving circuit (e.g., chip-on-film COF) in the bonding area BA.

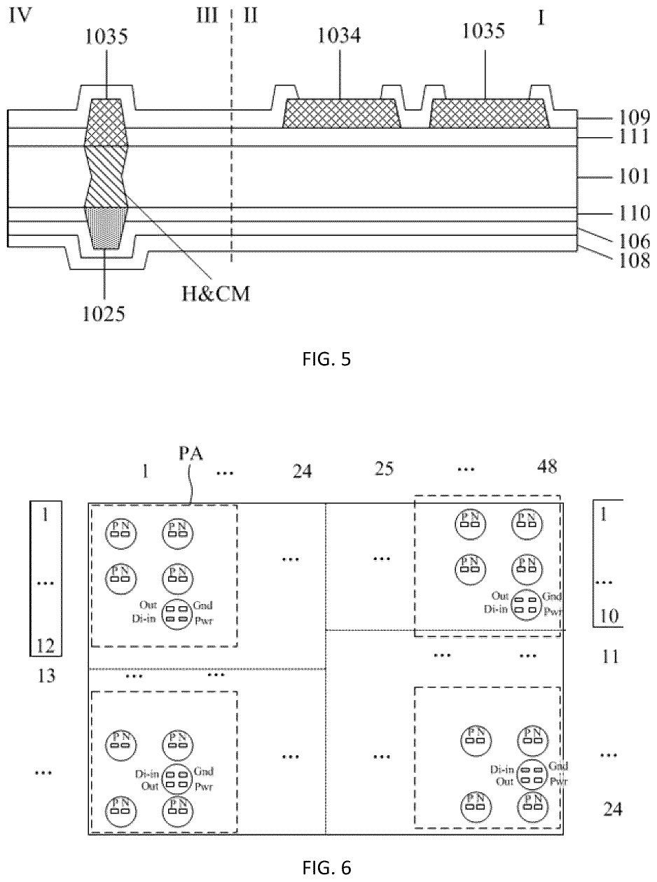

In some embodiments, in the wiring substrate according to embodiments of the disclosure, as illustrated in FIG. 5, to increase the adhesion of the signal lines 102 and connection lines 103 on the base substrate 101, a first buffer layer 110 may be provided between the base substrate and the layer where the signal lines 102 are located. Additionally, a second buffer layer 111 may be provided between the layer where the connection lines 103 are located and the base substrate 101. The first buffer layer 110 and the second buffer layer 111 are hollowed out at the vias H. Optionally, the materials of the first buffer layer 110 and the second buffer layer 111 include at least one of silicon oxide (SiOx), silicon nitride (SiNx), silicon oxynitride (SiON), aluminum oxide (AIOx), hafnium oxide (HfOx), and tantalum oxide (TaOx). Furthermore, as shown in FIGS. 2, 3, 8 to 10, the wiring substrate may further include an electrostatic ring 112, which is in the same layer and made of the same material as the signal lines 102, and surrounds the light-emitting area AA to prevent static electricity from damaging the components in the light-emitting area AA. It should be understood that other essential components of the wiring substrate should be considered as being included for those skilled in the art and are not further detailed here, and should not be considered as limitations of the disclosure.

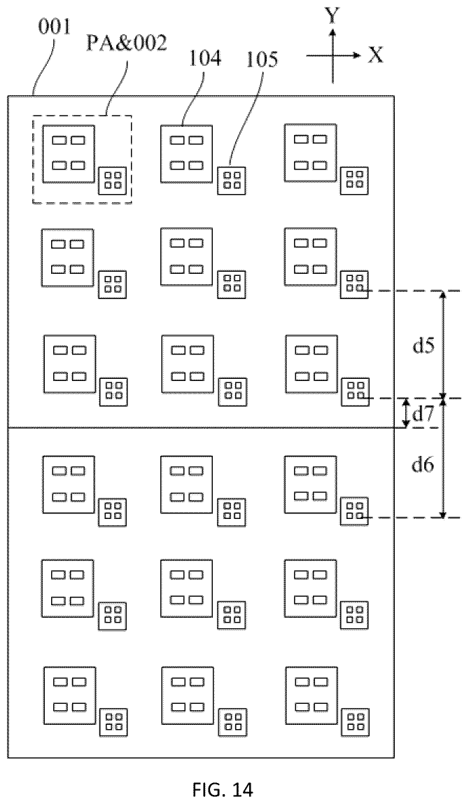

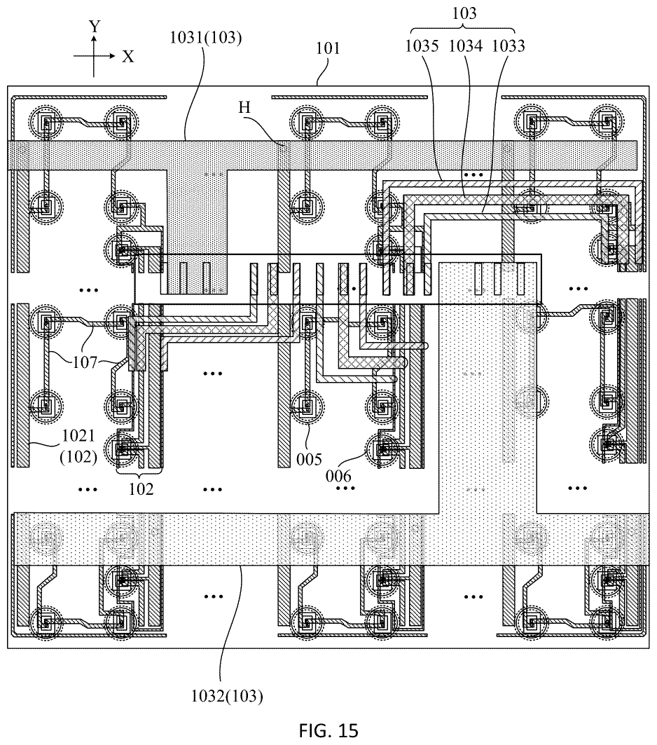

Based on the same inventive concept, embodiments of the disclosure further provides an electronic apparatus, as shown in FIGS. 14 and 15, which includes at least one wiring substrate 001 according to embodiments of the disclosure and a plurality of light-emitting structures 002 coupled with the plurality of signal lines 102. The specific implementations of the wiring substrate described above can be referenced for specific implementations of the electronic apparatus according to embodiments of the disclosure, where the details are not repeated here.

In cases where multiple wiring substrates 001 are spliced together to form a large-sized electronic apparatus, the size of the seam between adjacent wiring substrates 001 will affect the visual effect. Taking the splicing of multiple wiring substrates 001 along the second direction Y as an example, FIG. 15 shows a schematic diagram illustrating the splicing of two adjacent wiring substrates 001. Here, d5 indicates a spacing between adjacent rows of pad regions PA on the wiring substrate 001, d6 indicates a spacing between adjacent rows of pad regions PA at the splicing junction of the two wiring substrates 001, and d7 indicates a distance between the pad region PA closest to the splicing side closest to the wiring substrate 001 and the splicing edge. To achieve a better splicing visual effect, d5 should be equal to d6. During the splicing process of the two wiring substrates 001, if d5 is greater than d6, the two wiring substrates 001 can be separated by a certain distance, that is, increasing the spacing between the two wiring substrates 001; however, if d5 is less than d6, to achieve an ideal splicing effect, the splicing side of the wiring substrate 001 needs to have a narrower size, meaning the distance d7 between the pad region PA closest to the splicing side of the wiring substrate 001 and the splicing edge needs to be reduced. By arranging the fan-out region FA and bonding area BA on the second surface S2, the bottom bezel size (i.e., the distance d7 between the pad region PA closest to the splicing side of the wiring substrate 001 and the splicing edge) can be reduced, thereby facilitating the splicing required by large-sized electronic apparatus and ensuring good visual effects.

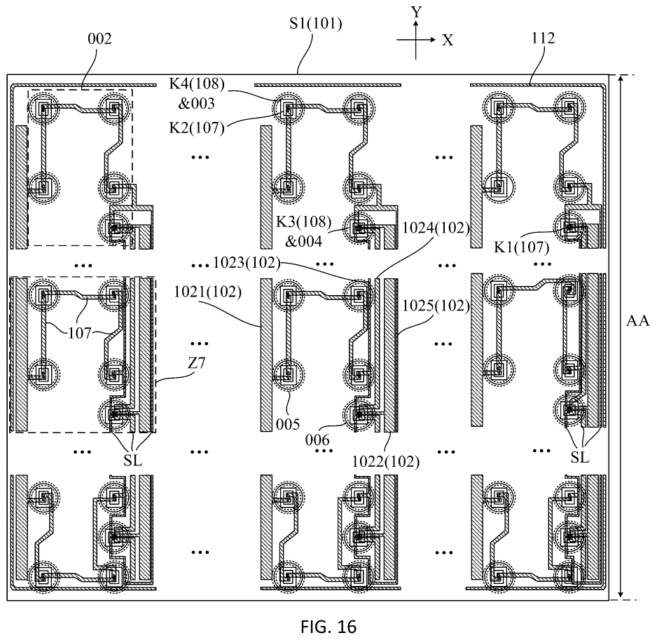

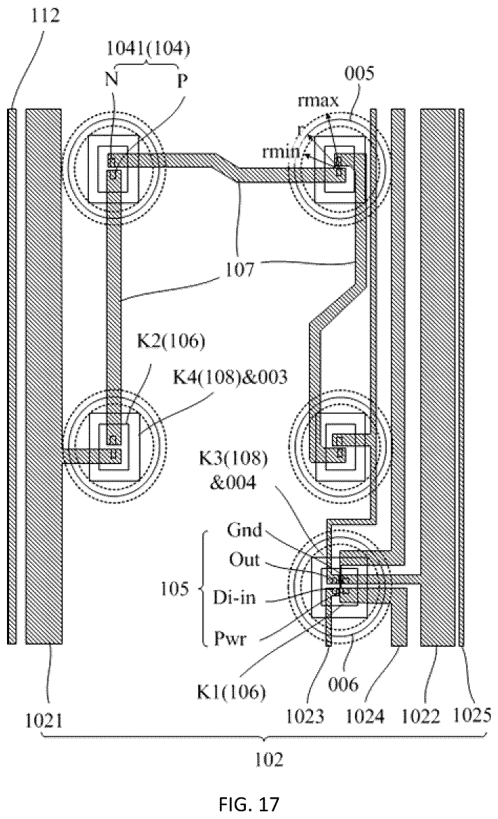

In some embodiments, as shown in FIGS. 16 and 17, in the electronic apparatus according to embodiments of the disclosure, the light-emitting structure 002 includes an electronic component 003 coupled with the first pad group 104 and a micro-drive chip 004 coupled with the second pad group 105. Optionally, an area of an orthographic projection of the micro-drive chip 004 on the base substrate 101 does not exceed 300,000 μm². The electronic component 003 is an LED, and a light-emitting area of the LED does not exceed 300,000 μm², and specifically does not exceed 40,000 μm². The LED has two pins, and each sub-pad group 1041 includes a first pad P and a second pad N, which are connected with the two pins of the LED respectively. It should be understood that if the electronic component 003 is another component, it can have a different number of pins, and correspondingly, each sub-pad group 1041 has a number of pads equal to the number of pins of the other component.

In some embodiments, the electronic apparatus according to embodiments of the disclosure, as shown in FIGS. 16 and 17, may further include multiple first transparent protection structures 005. An orthographic projection of each first transparent protection structure 005 on the base substrate 101 covers an orthographic projection of each electronic component 003 on the base substrate 101, providing protection to each electronic component 003. In cases where the electronic component 003 is an LED, the first transparent protection structure 005 can also enhance light efficiency.

In some embodiments, the first transparent protection structure 005 can be made using adhesive dispensing or screen printing techniques. Optionally, to achieve better protection and effectively improve light efficiency, the first transparent protection structure 005 may have a dome shape formed over the electronic component 003 (e.g., LED). Such a shape is referred to as a droplet lens, as illustrated in FIG. 17. A radius r of the orthographic projection of the first transparent protection structure 005 on the base substrate 101 can be 1450 μm. However, considering manufacturing deviations, which can be within +150 μm, the maximum radius r_max of the orthographic projection of the first transparent protection structure 005 on the base substrate 101 can be 1600 μm, and the minimum radius r_min can be 1400 μm.

Continuing with FIG. 17, in some embodiments, an orthographic projection of the fourth opening K4 on the base substrate 101 may be within the orthographic projection of the first transparent protection structure 005 on the base substrate 101. This means that the first transparent protection structure 005 completely covers the fourth opening K4, effectively reducing the likelihood of water and oxygen entering the wiring substrate 001 through the fourth opening K4 and causing corrosion of the signal lines 102. In some embodiments, if the orthographic projection of the fourth opening K4 on the base substrate 101 is larger than the orthographic projection of the first transparent protection structure 005 on the base substrate 101, meaning that the first transparent protection structure 005 partially covers the fourth opening K4, a white adhesive pattern may be added in the region where the fourth opening K4 exceeds the first transparent protection structure 005 to fill the gap and reduce the probability of water and oxygen entering the wiring substrate 001, thus effectively protecting the signal lines 102.

In some embodiments, as shown in FIGS. 16 and 17, the electronic apparatus according to embodiments of the disclosure may further include a second transparent protection structure 006. An orthographic projection of the second transparent protection structure 006 covers the orthographic projection of the micro-drive chip 004 on the base substrate 101, protecting the micro-drive chip 004. To facilitate manufacturing, the requirements for forming the second transparent protection structure 006 can be the same as those for the first transparent protection structure 005, and both can be formed in the same process.

Continuing with FIG. 17, in some embodiments, an orthographic projection of the third opening K3 on the base substrate 101 may be within the orthographic projection of the second transparent protection structure 006 on the base substrate 101. This means that the second transparent protection structure 006 completely covers the third opening K3, effectively reducing the likelihood of water an oxygen entering the wiring substrate 001 through the third opening K3 and causing corrosion of the signal lines 102. In some embodiments, if the orthographic projection of the third opening K3 on the base substrate 101 is larger than the orthographic projection of the second transparent protection structure 006 on the base substrate 101, meaning that the second transparent protection structure 006 partially covers the third opening K3, a white adhesive pattern may be added in the region where the third opening K3 exceeds the second transparent protection structure 006 to fill the gap and reduce the probability of water and oxygen entering the wiring substrate 001, thus effectively protecting the signal lines 102.

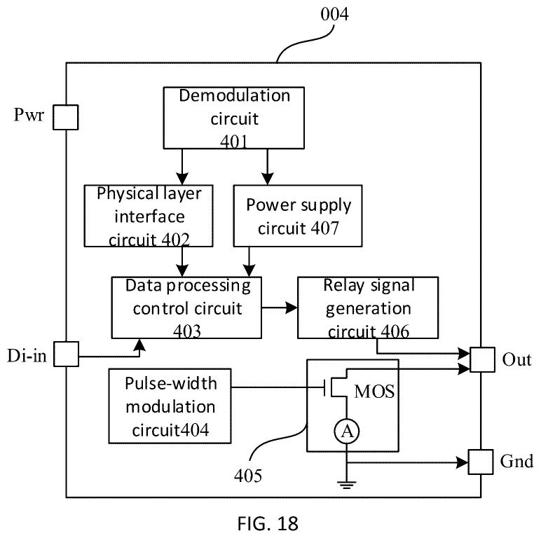

In some embodiments, in the electronic apparatus according to embodiments of the disclosure, as shown in FIG. 18, the micro-drive chip 004 may include a demodulation circuit 401, a physical layer interface circuit 402, a data processing control circuit 403, a pulse-width modulation circuit 404, a driving signal generation circuit 405, a relay signal generation circuit 406, and a power supply circuit 407.

In some embodiments, the demodulation circuit 401 is electrically connected with the power pads Pwr and the physical layer interface circuit 402, and is configured to demodulate the power line carrier communication signal input through the power pad Pwr to obtain communication data and transmit the obtained communication data to the physical layer interface circuit. When the electronic component 003 is an LED, the communication data may reflect the light emission duration, which indicates the required light intensity. Compared to the conventional Serial Peripheral Interface (SPI) protocol, the embodiments of the disclosure uses Power Line Carrier Communication (PLC) protocol to superimpose communication data on the power signal, effectively reducing the number of signal lines.

In some embodiments, the physical layer interface circuit 402 is also electrically connected with the data processing control circuit 403, and is configured to process the communication data to obtain data frames (e.g., frame rate data) and transmit the data frames to the data processing control circuit 403. The data frames obtained by the physical layer interface circuit 402 contain information to be transmitted to the micro-drive chip 004, such as information related to light emission duration (e.g., specific duration of light emission). Optionally, the physical layer interface circuit 402 is a typical physical layer (PHY), and detailed descriptions can be referred to in conventional designs, which are not repeated here.

In some embodiments, the data processing control circuit 403 is also electrically connected with the address pads Di, pulse-width modulation circuit 404, and relay signal generation circuit 406. The data processing control circuit 403 is configured to generate pulse-width control signals based on the data frames and transmit these pulse-width control signals to the pulse-width modulation circuit 404. The data processing control circuit 403 is further configured to generate relay control signals based on address signals and transmit the relay control signals to the relay signal generation circuit 406. For example, based on the data frames, the required light emission duration for the LED connected to the micro-drive chip 004 can be determined, and the corresponding pulse-width control signal is generated. For example, the relay control signal is a signal generated by the data processing control circuit 403 after processing the first input signal. By processing the address signals (e.g., parsing, latching, decoding, etc.), the address signal corresponding to the micro-drive chip 004 can be obtained, and a relay control signal corresponding to subsequent addresses, which correspond to other micro-drive chips 004, can be generated. Optionally, the data processing control circuit 403 can be implemented as a microcontroller, Central Processing Unit (CPU), digital signal processor, etc.

In some embodiments, the pulse-width modulation circuit 404 is also electrically connected with the driving signal generation circuit 405, and is configured to generate a pulse-width modulation signal in response to the pulse-width control signal and transmit the pulse-width modulation signal to the driving signal generation circuit 405. For example, the pulse-width modulation signal generated by the pulse-width modulation circuit 404 determines the light emission duration of the LED, for example, the effective pulse width duration is equal to the light emission duration of the LED.

In some embodiments, the driving signal generation circuit 405 is also electrically connected to the output pad Out, and is configured to generate a driving signal in response to the pulse-width modulation signal and output the driving signal through the output pad Out. Here, the driving signal being output through the output pad Out can indicate that the driving signal (e.g., driving current) flows from the output pad Out to the LED, or it can indicate that the driving signal (e.g., driving current) flows from the LED into the output pad Out, with the specific direction of current flow being not limited.

For example, in some embodiments, when the driving signal is a driving current, the driving signal generation circuit 405 may include a current source A and a MOS transistor. The control electrode of the MOS transistor receives the pulse-width modulation signal from the pulse-width modulation circuit 404, to be turned on or off under the control of the pulse-width modulation signal. The first terminal of the MOS transistor is connected to the output pad Out, and the second terminal of the MOS transistor is connected to the first terminal of the current source A. The second terminal of the current source A is connected to the ground pad Gnd to receive the common voltage. Optionally, the current source A can be a constant current source. When the pulse-width modulation signal is at an active level, the MOS transistor is turned on, and the current source A provides the driving current through the output pad Out. When the pulse-width modulation signal is at an inactive level, the MOS transistor is turned off, and the output pad Out does not provide the driving current. The duration of the active level of the pulse-width modulation signal equals the duration of the MOS transistor being turned on, and the duration of the MOS transistor being turned on equals the duration the driving current being provided through the output pad Out. This allows for further control of the LED's light emission duration, thereby controlling the visual brightness. In some embodiments, when the MOS transistor is turned on, the driving current flows from the output pad Out into the micro-drive chip 004, passing through the MOS transistor and the current source A, and then into the ground terminal (e.g., the ground pad Gnd). It should be noted that in the embodiments according to embodiments of the disclosure, the driving signal generation circuit 405 may adopt other circuit structures, which is not limited here.

In some embodiments, the relay signal generation circuit 406 is also electrically connected to the output pad Out, and is configured to generate relay signals based on the relay control signals and output the relay signals through the output pad Out. For example, the relay control signals correspond to subsequent addresses, and the relay signals generated based on the relay control signals contain the subsequent addresses, which correspond to other micro-drive chips 004. After the relay signal is output from the output pad Out, it is provided to the address pad Di of the next cascaded micro-drive chip 004, enabling the next cascaded micro-drive chip 004 to acquire the corresponding address signal. The relay signal generation circuit 406 can be implemented using latches, decoders, encoders, etc., which is not limited here.

It should be noted that in the embodiments of the disclosure, although both the driving signal generation circuit 405 and the relay signal generation circuit 406 are electrically connected to the output pad Out, they output the driving signal and relay signal during different time periods. The driving signal and relay signal are transmitted through the output pad Out by time division multiplexing, so they do not interfere with each other.

In some embodiments, the power supply circuit 407 is electrically connected to both the demodulation circuit 401 and the data processing control circuit 403, and is configured to receive electrical energy and supply power to the data processing control circuit 403. In some embodiments, after the demodulation circuit 401 demodulates the power line carrier communication signal input through the power pad Pwr, the DC power component (i.e., electrical energy) of the power line carrier communication signal is transmitted to the power supply circuit 407, and further provided to the data processing control circuit 403 by the power supply circuit 407. Of course, the embodiments of the disclosure are not limited to this, and the power supply circuit 407 may also be connected to other circuits in the micro-drive chip 004 to provide power. The power supply circuit 407 can be implemented using switch circuits, voltage conversion circuits, voltage regulation circuits, etc., which is not limited here.

It should be noted that the micro-drive chip 004 according to embodiments of the disclosure may include more circuits and components besides the aforementioned demodulation circuit 401, physical layer interface circuit 402, data processing control circuit 403, pulse-width modulation circuit 404, driving signal generation circuit 405, relay signal generation circuit 406, and power supply circuit 407. This depends on the functions that need to be implemented, which is not limited here.

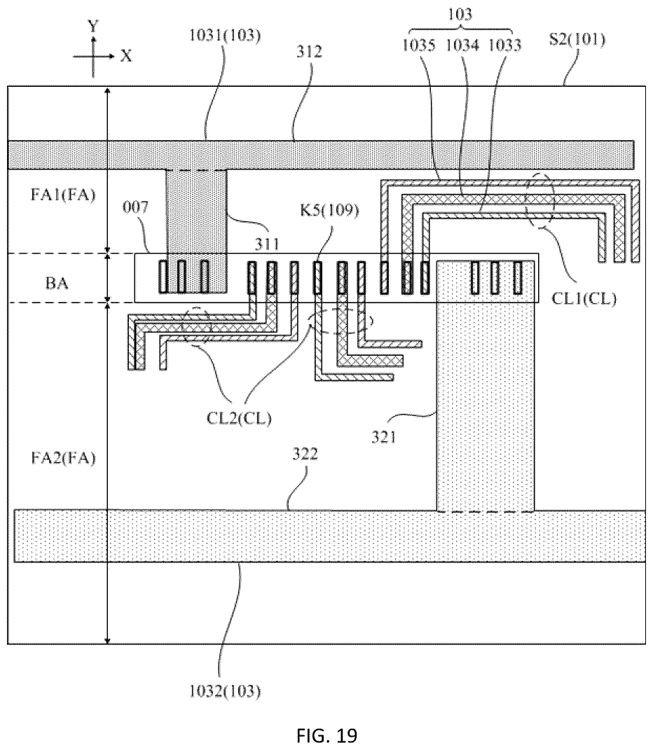

In some embodiments, as shown in FIG. 19, the electronic apparatus according to embodiments of the disclosure may further include a drive circuit board 007. The drive circuit board 007 is coupled with the plurality of connection lines 103 in the bonding area BA. Optionally, since there is ample wiring in the fan-out regions FA on both sides, the width of the connection lines 103 can be increased to reduce resistance and improve signal uniformity. Therefore, in large-sized electronic apparatuses, one drive circuit board 007 (e.g., one chip-on-film COF) can be used to load the driving signals for all the signal lines 102. Compared to related art, this approach can save 7 drive circuits (e.g., 7 chip-on-film COFs), demonstrating significant economic benefits and making connections and assembly more convenient after mass production.

In some embodiments, the electronic apparatus according to embodiments of the disclosure can be any product or component with display functionality, including but not limited to projectors, 3D printers, virtual reality devices, mobile phones, tablets, televisions, monitors, laptops, digital photo frames, navigation devices, smart watches, fitness bands, and personal digital assistants. Optionally, the electronic apparatus according to embodiments of the disclosure includes but is not limited to camera modules, ambient light sensors, RF units, network modules, audio output & input units, sensors, display units, user input units, interface units, and control chips. Optionally, the control chip can be a central processing unit (CPU), digital signal processor, system-on-chip (SoC), etc. For example, the control chip can further include memory, power modules, and other elements to achieve power supply and signal input/output functions. For example, the control chip can further include hardware circuits and computer-executable code. The hardware circuits can include conventional very-large-scale integration (VLSI) circuits or gate arrays, as well as existing semiconductors or other discrete components such as logic chips and transistors. The hardware circuits can further include field-programmable gate arrays, programmable array logic, programmable logic devices, etc.

Furthermore, it should be understood by those skilled in the art that the above structure does not limit the electronic apparatus according to embodiments of the disclosure. In other words, the electronic apparatus may include more or fewer components or combinations of components, or different component, based on the above mentioned structure.

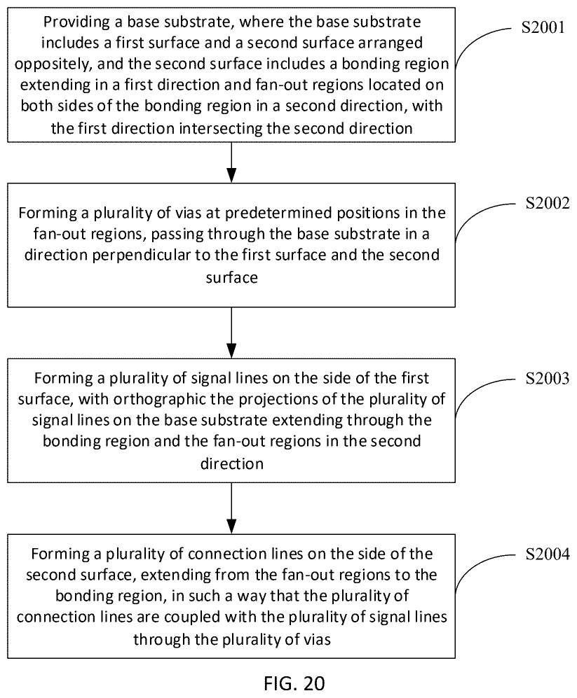

Based on the same inventive concept, embodiments of the disclosure further provide a manufacturing method for a wiring substrate, as shown in FIG. 20. The method may include the following steps.

S2001: providing a base substrate, where the base substrate includes a first surface and a second surface arranged oppositely, and the second surface includes a bonding region extending in a first direction and fan-out regions located on both sides of the bonding region in a second direction, with the first direction intersecting the second direction.

S2002: forming a plurality of vias at predetermined positions in the fan-out regions, passing through the base substrate in a direction perpendicular to the first surface and the second surface.

S2003: forming a plurality of signal lines on the first surface, with orthographic the projections of the plurality of signal lines on the base substrate extending through the bonding region and the fan-out regions in the second direction.

S2004: forming a plurality of connection lines on the second surface, extending from the fan-out regions to the bonding region, in such a way that the plurality of connection lines are coupled with the plurality of signal lines through the plurality of vias.

It should be understood that in the manufacturing method according to the embodiments of the disclosure, since the plurality of signal lines and the plurality of connection lines are located on opposite sides of the base substrate, the order of their manufacturing does not affect each other. Therefore, in the disclosure, either first step S2003 to manufacture the signal lines and then step S2004 to manufacture the connection lines can be executed, or first step S2004 to manufacture the connection lines and then step S2003 to manufacture the signal lines can be executed, which is not limited here. Additionally, since the principle of solving problems with this manufacturing method is similar to the principle for solving problems with the wiring substrate described above, the implementation of the manufacturing method can refer to the implementation of the wiring substrate described in the disclosure, with repetitive details omitted.

To better understand the manufacturing method for the wiring substrate according to embodiments of the disclosure, the following is a detailed description.

Optionally, the manufacturing method for the wiring substrate according to embodiments of the disclosure, as shown in FIG. 2, may include the following steps.

In step 1, a base substrate 101 is provided. The base substrate includes a first surface S1 and a second surface S2 arranged oppositely. The second surface S2 includes a bonding region BA extending in a first direction X and fan-out regions FA (indicated as a first fan-out region FA1 and a second fan-out region FA2) located on both sides of the bonding region BA in a second direction Y, where the first direction X intersects the second direction Y. Optionally, the base substrate 101 can be a glass substrate, which is characterized by good thermal conductivity, high flatness, and low expansion coefficient, making it suitable for COB (chip-on-board) packaging of LEDs. Additionally, glass substrates are relatively low-cost and easily accessible, making them suitable for large-sized products.

In step 2, before drilling, the coordinates of the vias in the base substrate 101 (i.e., the coupling positions of the signal lines 102 and connection lines 103) can be determined through design drawings; then, laser drilling technology or etching liquid etching methods can be used to form a plurality of vias H passing through the base substrate 101 in a direction perpendicular to the first surface S1 and second surface S2 (e.g., the diameter of the via H is 0.2 mm).

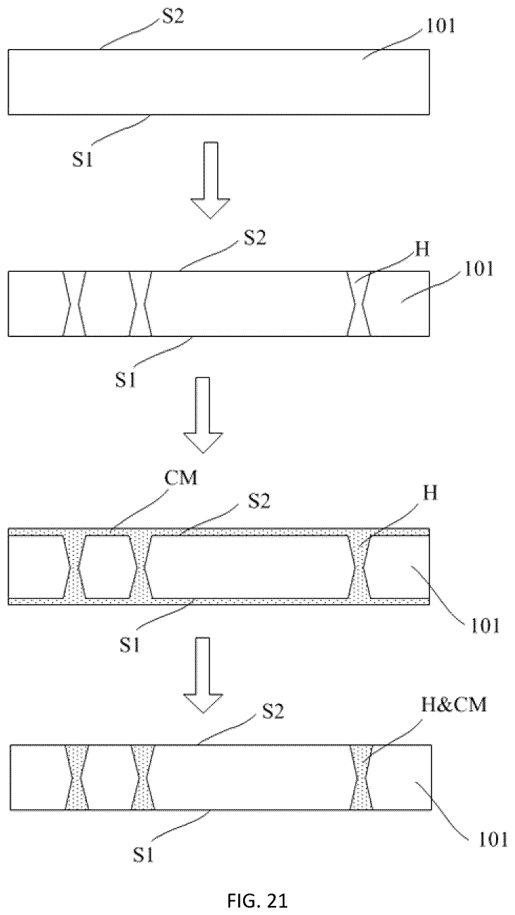

Laser drilling technology uses high-power density laser beams to irritate the material to make the material to be heated rapidly to vaporization temperature, creating holes. Due to the fast speed, high efficiency, cost-effectiveness, and wide application, laser drilling is widely used in industrial production. In the disclosure, the process of laser drilling and filling conductive materials is shown in FIG. 21. Specifically, the plurality of vias H are formed on the prepared base substrate 101 using laser drilling according to the coordinates. Then, conductive material CM (e.g., Cu) is deposited on at least one of the first surface S1 and second surface S2 of the drilled substrate 101 to completely fill the vias H with the conductive material CM. Further, the first surface and the second surface of the base substrate 101 both are covered with the conductive material CM. Chemical-mechanical planarization (CMP) can then be used to remove the excess conductive material CM from the first surface S1 and second surface S2, leaving only the conductive material CM inside the vias H to prevent interference with the subsequent manufacturing of the signal lines 102 and connection lines 103. It should be noted that due to temperature differences and varying burn ranges during laser drilling on glass, the inner and outer diameters of the vias may differ. FIG. 19 merely shows a general shape of the via H. In some embodiments, the shape of the vias H can vary, such as circular, elliptical, triangular, square, rectangular, diamond, trapezoidal, pentagonal, regular polygons (e.g., regular octagon), etc., which can be regular or non-regular, and is not limited here.

In step 3, a second buffer layer 111 is formed on the second surface S2. The second buffer layer 111 is hollowed out at the vias H to expose the vias H, facilitating the coupling of the subsequent connection lines 103 and signal lines 102 at the vias H.

In step 4, multiple connection lines 103 are formed on the second buffer layer 111. The multiple connection lines 103 extend from the fan-out regions FA to the bonding region BA, and the connection lines 103 are coupled with the multiple signal lines 102 through the multiple vias H.

In step 5, a second insulating layer 109 is formed on the layer with the multiple connection lines 103. Optionally, the second insulating layer 109 has fifth openings K5 in the bonding region BA to expose the connection lines 103 in the bonding region BA, facilitating the bonding connection of the connection lines 103 with the drive circuit (e.g., chip-on-film COF) in the bonding region BA.

In step 6, a first buffer layer 110 is formed on the first surface S1. The first buffer layer 110 is hollowed out at the vias H to expose the vias H, facilitating the coupling of the subsequent signal lines 102 and connection lines 103 at the vias H.

In step 7, multiple signal lines 102 and multiple routing lines 107 are formed on the first buffer layer 110. The orthographic projections of the signal lines 102 on the base substrate 101 extend in the second direction Y through the bonding region BA and fan-out regions FA and are coupled with the connection lines 103 at the vias H. Optionally, portions of the multiple signal lines 102 can serve as output pads Out, address pads Di-in, power supply pads Pwr, and ground pads Gnd in the second pad group 105, while portions of the multiple routing lines 107 can serve as the first pad P and second pad N in the sub-pad group 1041.

In step 8, a first insulating layer 106 is formed on the side of the layer with the multiple signal lines 102, away from the base substrate 101. The first insulating layer 106 includes second openings K2 exposing the sub-pad groups 1041 and first openings K1 exposing the second pad groups 105.

In step 9, a reflective layer 108 is formed on the layer with the first insulating layer 106. The reflective layer 108 includes fourth openings K4 exposing the sub-pad groups 1041 and third openings K3 exposing the second pad groups 105.

As such, the manufacturing of the wiring substrate as shown in FIG. 2 is complete.

It should be noted that, in the disclosure, the formation of film layers on the second surface S2 are completed through steps 3 to 5, and then the formation of the film layer on the first surface S1 are completed through steps 6 to 9. In some embodiments, steps 6 to 9 for forming the film layers on the first surface S1 can be executed first, and then steps 3 to 5 for forming the film layers on the second surface S2 can be executed. In some embodiments, the manufacturing sequence can be step 3→step 6→step 4→step 7→step 5→step 8→step 9, to complete the formation of the film layers on both the first surface S1 and the second surface S2. The sequence of film layer formation on the first surface S1 and the second surface S2 is not strictly limited in the disclosure.

Further, after completing the wiring substrate as shown in FIG. 2, electronic components 003 (e.g., LEDs) can be bonded to the sub-pad group 1041, a micro-drive chip 004 can be bonded to the second pad group 105, and a first transparent protection structure 005 covering the electronic components 003 and a second transparent protection structure 006 covering the micro-drive chip 004 can be set. Finally, a drive circuit 007 (e.g., chip-on-film COF) can be bonded in the bonding region BA, completing the manufacturing of the electronic apparatus.

It should be noted that in the manufacturing method according to embodiments of the disclosure, the patterning process related to the formation of each film layer structure can include part of all the processes including deposition, photoresist coating, mask alignment, exposure, development, etching, and photoresist removal, and can further include other processes depending on the required patterns during the actual manufacturing process. For example, a post-baking process may be included between development and etching processes. Deposition processes can include chemical vapor deposition, plasma-enhanced chemical vapor deposition, or physical vapor deposition. The masking process can use a half-tone mask, single slit mask, or gray tone mask, which is not limited here. Etching can be dry or wet etching, which is not limited in the disclosure.

Although the preferred embodiments of the disclosure have been described, those skilled in the art can make additional changes and modifications to these embodiments once they know the basic inventive concepts. Therefore, the appended claims are intended to be explained as including the preferred embodiments and all changes and modifications falling within the scope of the disclosure.

Obviously, those skilled in the art can make various changes and modifications to the embodiments of the disclosure without departing from the spirit and scope of the embodiments of the disclosure. Thus, if these changes and modifications of the embodiments of the disclosure fall within the scope of the claims of the disclosure and their equivalents, the disclosure is also intended to include these changes and modifications.

1. A wiring substrate, comprising:
a base substrate comprising a first surface and a second surface arranged oppositely, wherein the second surface comprises a bonding region extending in a first direction and fan-out regions located on both sides of the bonding region in a second direction, the fan-out regions are provided with a plurality of vias, and the first direction intersects the second direction;
a plurality of signal lines on the first surface, wherein orthographic projections of the plurality of signal lines on the base substrate extend in the second direction, passing through the bonding region and the fan-out regions; and
a plurality of connection lines on the second surface, wherein the plurality of connection lines extend from the fan-out regions to the bonding region, and the plurality of connection lines are coupled with the plurality of signal lines through the plurality of vias.

2. The wiring substrate according to claim 1, wherein the bonding region is located in a middle region of the second surface.

3. The wiring substrate according to claim 1 or 2, wherein the fan-out regions on both sides of the bonding region are indicated as a first fan-out region and a second fan-out region, respectively;
the plurality of connection lines comprise a constant voltage signal connection line and a common voltage signal connection line;
the constant voltage signal connection line extends from the first fan-out region to the bonding region, and the common voltage signal connection line extends from the second fan-out region to the bonding region.

4. The wiring substrate according to claim 3, wherein the constant voltage signal connection line comprises a first constant voltage signal connection part extending in the second direction, and the common voltage signal connection line comprises a first common voltage signal connection part extending in the second direction;
the first constant voltage signal connection part extends from the first fan-out region to the bonding region, and the first common voltage signal connection part extends from the second fan-out region to the bonding region, and the first common voltage signal connection part and the first constant voltage signal connection part are staggered in the first direction.

5. The wiring substrate according to claim 4, wherein the plurality of signal lines comprise a plurality of constant voltage signal lines extending in the second direction and arranged in the first direction;
the constant voltage signal connection line further comprises a second constant voltage signal connection part integrally formed with the first constant voltage signal connection part;
wherein the second constant voltage signal connection part extends in the first direction within the first fan-out region, and is coupled with the plurality of constant voltage signal lines.

6. The wiring substrate according to claim 5, wherein a line width of the second constant voltage signal connection part in the second direction is greater than or equal to 28 mm.

7. The wiring substrate according to claim wherein the plurality of connection lines further comprise a plurality of connection line groups, and the plurality of connection line groups comprise a plurality of first connection line groups;
wherein the plurality of first connection line groups are located at a side of the first constant voltage signal connection part close to the first common voltage signal connection part, and at a side of the second constant voltage signal connection part close to the bonding region.

8. The wiring substrate according to claim 7, wherein the first surface comprises 2n*2m pad regions, wherein n and m are integers greater than 2;
the plurality of signal lines further comprise 2m signal line groups arranged sequentially in the first direction, and the signal line groups are located between adjacent constant voltage signal lines and pass through the pad regions in the second direction;
an (m+1)-th signal line group to a 2m-th signal line group are coupled with the plurality of first connection line groups in a (n-q)-th row of the pad regions;
wherein q is an integer nearest to W1/W2 and greater than W1/W2, W1 indicates a size of the bonding region in the second direction, and W2 indicates a size of the pad region in the second direction.

9. The wiring substrate according to claim 4, wherein the plurality of signal lines further comprise a plurality of common voltage signal lines extending in the second direction and arranged in the first direction;
the common voltage signal connection line further comprises a second common voltage signal connection part integrally formed with the first common voltage signal connection part;
wherein the second common voltage signal connection part extends in the first direction within the second fan-out region, and is coupled with the plurality of common voltage signal lines.

10. The wiring substrate according to claim 9, wherein a line width of the second common voltage signal connection part in the second direction is greater than or equal to 28 mm.

11. The wiring substrate according to claim 9 wherein the plurality of connection lines further comprise a plurality of connection line groups, and the plurality of connection line groups comprise a plurality of second connection line groups;
wherein the plurality of second connection line groups are located at a side of the first common voltage signal connection part close to the first constant voltage signal connection part, and at a side of the second common voltage signal connection part close to the bonding region.

12. The wiring substrate according to claim 11, wherein the first surface comprises 2n*2m pad regions, and n and m are integers greater than 2;
the plurality of signal lines further comprise 2m signal line groups arranged sequentially in the first direction and passing through the pad regions in the second direction;
a first signal line group to an m-th signal line group are coupled to the plurality of second connection line groups in a n-th row of pad regions.

13. The wiring substrate according to claim 8 wherein the signal line group comprises an address signal line, a power signal line and a feedback signal line, and the connection line group comprises an address signal connection line, a power signal connection line and a feedback signal connection line;
wherein the address signal connection line is coupled with the address signal line, the power signal connection line is coupled with the power signal line, the feedback signal connection line is coupled with the feedback signal line;
in a 2n-th row of pad regions, the address signal line and the feedback signal line of a same signal line group are integrally formed.

14. The wiring substrate according to claim 13, wherein a line width of the address signal connection line is greater than or equal to 0.1 mm, a line width of the power signal connection line is greater than or equal to 0.2 mm, and a line width of the feedback signal connection line is greater than or equal to 0.1 mm.

15. The wiring substrate according to claim to 1, wherein the first surface comprises 2n*2m pad regions, and n and m are integers greater than 2;
the pad region is provided with a first pad group and a second pad group, and the first pad group comprises at least two sub-pad groups;
in at least a 2n-th row of pad regions, the second pad group is located between adjacent sub-pad groups of the at least two sub-pad groups.

16. The wiring substrate according to claim to 1, further comprising an insulating layer on a side of the plurality of connection lines away from the base substrate;
wherein the insulating layer comprises a plurality of openings in the bonding region, and in the bonding region, orthographic projections of some of the plurality of connection lines on the base substrate are located within orthographic projections of the plurality of openings on the base substrate.

17. An electronic apparatus, comprising:
at least one wiring substrate according to claim 1; and
a plurality of light-emitting structures coupled with the plurality of signal lines.

18. The electronic apparatus according to claim 17, wherein the first surface comprises a plurality of pad regions;
wherein the pad region is provided with a first pad group and a second pad group, the light-emitting structure comprises an electronic component coupled with the first pad group and a micro drive chip coupled with the second pad group.

19. The electronic apparatus according to claim 17, further comprising a drive circuit board;
wherein the drive circuit board is coupled with the plurality of connection lines in the bonding region;
wherein the drive circuit board comprises a chip-on-film (COF).

20. (canceled)

21. A manufacturing method for a wiring substrate, comprising:
providing a base substrate; wherein the base substrate comprises a first surface and a second surface arranged oppositely, the second surface comprises a bonding region extending in a first direction and fan-out regions on both sides of the bonding region in a second direction, and the first direction intersects the second direction;
forming a plurality of vias at predetermined positions in the fan-out regions, wherein the plurality of vias pass through the base substrate in a direction perpendicular to the first surface and the second surface;
forming a plurality of signal lines on the first surface; wherein orthographic projections of the plurality of signal lines on the base substrate extend in the second direction, passing through the bonding region and the fan-out regions;
forming a plurality of connection lines, extending from the fan-out regions to the bonding region, on the second surface, in such a way that the plurality of connection lines are coupled with the plurality of signal lines through the plurality of vias.
